(19) United States
(12) Patent Application Publication
(10) Pub. No.: US 2026/0157224 A1
(43) Pub. Date: Jun. 4, 2026

(54) SELF-ALIGNED DIE-TO-WAFER BONDING ARCHITECTURE

(71) Applicant: Sandisk Technologies, Inc., Milpitas, CA (US)

(72) Inventors: Chengqing Hu, Milpitas, CA (US); Henry Chin, Fremont, CA (US); Nagesh Vodrahalli, Los Altos, CA (US)

(21) Appl. No.: 18/963,996

(22) Filed: Nov. 29, 2024

(51) Int. Cl. H01L 23/00

(52) U.S. Cl. CPC H10W 74/134; H10W 74/141; H10W 72/0198; H10W 80/011; H10W 80/016; H10W 80/165; H10W 80/312; H10W 90/792

(57) ABSTRACT

A semiconductor package assembly process uses a self-aligning die-to-wafer bonding process that aligns interconnects of a semiconductor die with corresponding interconnects of a wafer. A surface preparation process assists in the accurate alignment of the die and the wafer. The surface preparation process is used to define a liquid confinement area that helps ensure accurate alignment. Additionally, the surface preparation process helps ensure that the bonding surfaces of the wafer and the die are smooth and free from debris, which enhances a bond quality between the interconnects of each component. When the surfaces of the wafer and the die have been prepared, the self-aligning die-to-wafer bonding process utilizes surface tension to align the interconnects of the die with the interconnects of the wafer.

### BACKGROUND

As semiconductor dies and packages are getting smaller and more complex, die-to-wafer bonding is emerging as a suitable alternative to solder bonding and wafer-to-wafer bonding. In a die-to-wafer bonding process, interconnects on a semiconductor die are directly bonded to corresponding interconnects on the wafer. However, as the size of the semiconductor die decreases, the size and/or the pitch of the interconnects on the semiconductor die, and the size and/or the pitch of the interconnects on the wafer, also decreases.

Due to the decreased size and/or pitch of the interconnects, and due to the precise alignment requirements of semiconductor packaging, it becomes increasingly difficult to accurately align and couple the interconnects during assembly of a semiconductor package. As a result, it takes additional time to fully assemble the semiconductor package which can negatively impact the throughput and yield of the semiconductor package assembly process.

Accordingly, it would be beneficial to improve the accuracy and speed of a die-to-wafer bonding process to increase yield and throughput of a semiconductor package assembly process.

### SUMMARY

The present application describes a semiconductor package assembly process that

utilizes a self-aligning die-to-wafer bonding process that accurately and efficiently aligns interconnects of a semiconductor die with corresponding interconnects on a wafer to which the semiconductor die will be coupled. In an example, the self-aligning die-to-wafer bonding process employs a surface preparation process that assists in the accurate alignment of the semiconductor die and the wafer.

As will be described in greater detail herein, a surface of the semiconductor die and a surface of the wafer will both undergo the same, or similar, surface preparation processes. The surface preparation process, and the subsequent self-aligning die-to-wafer bonding process, results in higher die-to-wafer bonding throughput and higher bonding alignment accuracy (e.g., sub-500 nanometers (nm)) when compared with conventional die-to-wafer bonding techniques.

In an example, when the surfaces of the wafer and the semiconductor die have been prepared using the surface preparation process, the self-aligning die-to-wafer bonding process utilizes surface tension to align the interconnects of the semiconductor die with the interconnects of the wafer. For example, one or more liquid drops are placed on a bonding surface, or a target surface, of the wafer. A bonding surface of the semiconductor die is brought (e.g., by a pick and place machine) into contact with the liquid. When the semiconductor die is released by the pick and place machine, a capillary force of the liquid causes the bonding surface of the semiconductor die to align with the bonding surface of the wafer. Once the bonding surfaces are aligned, the liquid is evaporated and a bonding process commences.

As will be explained in greater detail herein, each bonding surface is associated with a liquid confinement area or feature which helps ensure accurate alignment. Additionally, the surface preparation process helps ensure that the bonding surface of the wafer and the semiconductor die is smooth and free from debris, which enhances the bonding quality between the interconnects of each component.

Accordingly, examples of the present disclosure describe a method that includes forming a mesa on a surface of a wafer. In an example, the mesa includes at least one bond pad. A hydrophobic material is placed on the surface of the wafer such that at least a portion of the mesa is covered by the hydrophobic material. At least a portion of the hydrophobic material is covered with a polymer film. The hydrophobic material and the polymer film is then removed from a surface of the mesa. A remaining portion of the polymer film is also removed from the surface of the wafer. The at least one bond pad on the mesa is then de-oxidized.

The present disclosure also describes a semiconductor package that includes a wafer and an array dielet. In an example, the wafer includes an elevated portion and a non-elevated portion. The elevated portion of the wafer has at least one bond pad and has hydrophilic properties. A hydrophobic layer covers at least a portion of the non-elevated portion of the wafer and at least a portion of a sidewall of the elevated portion of the wafer. The array dielet also has an elevated portion and non-elevated portion. In an example, the elevated portion of the array dielet includes at least one bond pad and has hydrophilic properties. In an example, the at least one bond pad of the array dielet is directly bonded to the at least one bond pad of the wafer. A hydrophobic layer covers at least a portion of the non-elevated portion of the array dielet and at least a portion of a sidewall of the elevated portion of the array dielet. The semiconductor package also includes an epoxy molding compound that at least partially encapsulates the elevated portion of the array dielet and the elevated portion of the wafer.

Additional examples describe a semiconductor package that includes a wafer and a semiconductor die. In an example, the wafer has a first liquid confinement area that includes a first interconnection means. The first liquid confinement area also has hydrophilic properties. In an example, a first liquid repelling means defines the first liquid confinement area. The semiconductor package also includes a semiconductor die. In an example, the semiconductor die has a second liquid confinement area that includes a second interconnection means. The second liquid confinement area also has hydrophilic properties and is defined by a second liquid repelling means. The semiconductor package also includes an encapsulation means. In an example, the encapsulation means at least partially encapsulates the wafer and the semiconductor die.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 illustrates a semiconductor package according to an example.

FIG. 2 illustrates a wafer for a semiconductor package undergoing a first operation of a surface preparation process that is part of a self-aligning die-to-wafer bonding process according to an example.

FIG. 3 illustrates the wafer of FIG. 2 undergoing a second operation of the surface preparation process according to an example.

FIG. 4 illustrates the wafer of FIG. 3 undergoing a third operation of the surface preparation process according to an example.

FIG. 5 illustrates the wafer of FIG. 4 undergoing a fourth operation of the surface preparation process according to an example.

FIG. 6 illustrates the wafer of FIG. 5 undergoing a fifth operation of the surface preparation process according to an example.

FIG. 7 illustrates the wafer of FIG. 6 undergoing a sixth operation of the surface preparation process according to an example.

FIG. 8 illustrates the wafer of FIG. 7 undergoing a seventh operation of the surface preparation process according to an example.

FIG. 9 illustrates the wafer of FIG. 8 undergoing an eighth operation of the surface preparation process according to an example.

FIG. 10 illustrates the wafer of FIG. 9 undergoing a ninth operation of the surface preparation process according to an example.

FIG. 11 illustrates the wafer of FIG. 10 undergoing a tenth operation of the surface preparation process according to an example.

FIG. 12 illustrates the wafer of FIG. 11 undergoing an eleventh operation of the surface preparation process according to an example.

FIG. 13 illustrates semiconductor dies undergoing a twelfth operation of the surface preparation process according to an example.

FIG. 14 illustrates the semiconductor die of FIG. 13 undergoing a thirteenth operation of the surface preparation process according to an example.

FIG. 15 illustrates a first operation of a self-aligning die-to-wafer bonding process according to an example.

FIG. 16 illustrates a second operation of the self-aligning die-to-wafer bonding process shown and described with respect to FIG. 15 according to an example.

FIG. 17 illustrates a third operation of the self-aligning die-to-wafer bonding process shown and described with respect to FIG. 16 according to an example.

FIG. 18 illustrates a fourth operation of the self-aligning die-to-wafer bonding process shown and described with respect to FIG. 17 according to an example.

FIG. 19 illustrates a fifth operation of the self-aligning die-to-wafer bonding process shown and described with respect to FIG. 18 according to an example.

FIG. 20 illustrates a first operation of a semiconductor package assembly process according to an example.

FIG. 21 illustrates a second operation of the semiconductor package assembly process according to an example.

FIG. 22 illustrates a third operation of the semiconductor package assembly process according to an example.

FIG. 23 illustrates a fourth operation of the semiconductor package assembly process according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. Examples may be practiced as methods, systems or devices. Accordingly, examples may take the form of a hardware implementation, an entirely software implementation, or an implementation combining software and hardware aspects. The following detailed description is therefore not to be taken in a limiting sense, and the scope of the present disclosure is defined by the appended claims and their equivalents.

Semiconductor dies and packages are getting smaller and more complex. As semiconductor dies and packages get smaller, a size and/or a pitch between various interconnects of the semiconductor package also get smaller. As result, it becomes increasingly difficult to accurately align and bond the interconnects of the semiconductor package (e.g., align and bond the interconnects of the semiconductor die with the interconnects of a wafer or a printed circuit board (PCB)).

Die-to-wafer bonding is a process in which interconnects on the semiconductor die are directly bonded to corresponding interconnects on the wafer. However, due to the small size and close pitch of the interconnects, precisely aligning the interconnects increases the assembly time and reduces throughput of semiconductor packages that are assembled using this type of bonding process.

To address this, the present application describes a semiconductor package assembly process that utilizes a self-aligning die-to-wafer bonding process. The self-aligning die-to-wafer bonding process accurately and efficiently aligns interconnects of a semiconductor die with corresponding interconnects on a wafer to which the semiconductor die will be coupled.

The self-aligning die-to-wafer bonding process also includes a surface preparation process. As will be described in greater detail herein, the surface preparation process, along with the self-aligning bonding process, results in higher die-to-wafer bonding throughput and higher bond alignment accuracy when compared with conventional die-to-wafer bonding techniques.

The self-aligning bonding process utilizes surface tension to align the interconnects of the semiconductor die with the interconnects of the wafer. For example, when a bonding surface of the wafer has been prepared, one or more liquid drops are placed on the bonding surface of the wafer. A bonding surface of the semiconductor die is brought (e.g., by a pick and place machine) into contact with the liquid. When the pick and place machine releases the semiconductor die, a capillary force of the liquid causes the bonding surface of the semiconductor die to align with the bonding surface of the wafer. Once the bonding surfaces are aligned, the liquid is evaporated and interconnects of the semiconductor die are directly bonded with interconnects of the wafer.

As will be explained in greater detail herein, the bonding surface of the wafer and the bonding surface of the semiconductor die have, or are otherwise associated with, a liquid confinement area. The liquid confinement area helps ensure accurate alignment between the wafer and the semiconductor die. Additionally, the surface preparation process helps ensure that the bonding surface of the wafer and the bonding surface of the semiconductor die are smooth and free from debris. As a result, a bonding quality between the interconnects of the wafer and the semiconductor die is enhanced.

Accordingly, many technical benefits may be realized including, but not limited to, increasing the accuracy of interconnect alignment (e.g., sub-500 nanometer (nm) alignment) when compared with conventional die-to-wafer bonding techniques, increasing the throughput and yield of semiconductor die assembly, and increasing a bond quality of the interconnects of a semiconductor die and a wafer when compared with conventional die-to-wafer bonding techniques.

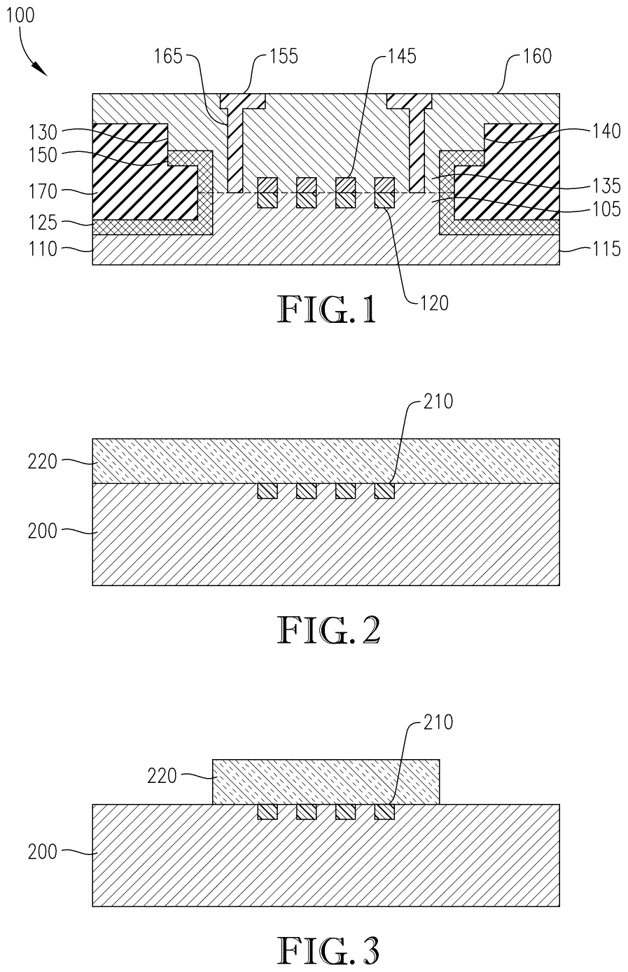

These various benefits and examples will be described in greater detail below with reference to FIG. 1-FIG. 23.

FIG. 1 illustrates a semiconductor package 100 according to an example. In an example, the semiconductor package 100 is manufactured or assembled using a self-aligning die-to-wafer bonding process such as will be described in greater detail herein. In an example, the self-aligning die-to-wafer bonding process includes a surface preparation process. The surface preparation process helps ensure the surfaces of each component of the semiconductor package are smooth and are free from debris and other contaminants. As a result, a bond quality of the interconnects of the components is increased when compared with conventional die-to-wafer bonding techniques.

In an example, the semiconductor package 100 includes a wafer 110 and a semiconductor die 130. In FIG. 1, the wafer 110 and the semiconductor die are delineated by the dash line. The wafer 110 may be any type of semiconductor wafer and/or be comprised of a dielectric material. The wafer 110 may also be comprised of a number of different layers and have various interconnects, traces, through silicon vias and the like.

In this example, the wafer 110 includes a first surface, or a top surface. The first surface of the wafer 110 includes an elevated portion 105 (also referred to as a “mesa”) and a non-elevated portion 115. The elevated portion 105 includes physical and chemical contrasts when compared with the non-elevated portion 115. For example, the elevated portion 105 is raised with respect to the non-elevated portion 115 to provide or define a bonding surface of the wafer 110.

Additionally, the elevated portion 105 includes one or more interconnects 120. In an example, the interconnects 120 are copper pads. Although copper pads are specifically mentioned, the interconnects 120 may be comprised of any material or combination of materials.

In an example, the elevated portion 105 is hydrophilic or has hydrophilic properties. The hydrophilic properties of the elevated portion 105 enables water, or other liquids, that are used to align the semiconductor die 130 to the wafer 110 as part of the self-aligning die-to-wafer bonding process, to attract and maintain the liquid on the elevated portion 105 during the self-aligning die-to-wafer bonding process.

The non-elevated portion 115 of the wafer 110 includes a hydrophobic layer 125 or material. The hydrophobic layer 125 helps create a or define a liquid confinement area. For example, the hydrophobic layer 125 creates a chemical contrast between the elevated portion 105 and the non-elevated portion 115 and helps ensure that the liquid that is used as part of the self-aligning die-to-wafer bonding process remains on, or is contained on, the elevated portion 105 of the wafer 110.

In an example, the hydrophobic layer 125 covers or substantially covers the non-elevated portion 115. Additionally, the hydrophobic layer extends, at least partially, along a sidewall of the elevated portion 105.

As previously discussed, the semiconductor package 100 also includes a semiconductor die 130. In an example, the semiconductor die 130 is a memory die, such as, for example, a NAND memory die. Although a semiconductor die 130 is described, the semiconductor package 100 can include an array of semiconductor dies, a semiconductor dielet, an array of semiconductor dielets, a semiconductor chiplet, an array of semiconductor chiplets and so on. The dielets and/or the chiplets may be memory-based and/or may perform a number of different functions, operations and/or processes.

Like the wafer 110, the semiconductor die 130 includes a first surface, or a top surface. The first surface of the semiconductor die 130 includes an elevated portion 135 and a non-elevated portion 140. Like the elevated portion 105 of the wafer 110, the elevated portion 135 of the semiconductor die 130 includes physical and/or chemical contrasts when compared with the non-elevated portion 140. For example, the elevated portion 135 of the semiconductor die 130 is raised with respect to the non-elevated portion 140 to provide or define a bonding surface of the semiconductor die 130.

Additionally, the elevated portion 135 of the semiconductor die 130 includes one or more interconnects 145. In an example, the interconnects 145 are copper pads. Although copper pads are specifically mentioned, the interconnects 145 may be comprised of any material or combination of materials.

In an example, the elevated portion 105 is hydrophilic, or has hydrophilic properties, that assist in aligning the elevated portion 135 (and/or a bonding surface) of the semiconductor die 130 to the elevated portion 105 (and/or the bonding surface) of the wafer 110. For example, the hydrophilic properties of each of the elevated portions enables capillary force provided by a liquid to help ensure the bonding surface of the wafer 110 and the bonding surface of the semiconductor die 130, along with the interconnects 120 of the wafer 110 and the interconnects 145 of the semiconductor die 130, are aligned as part of the self-aligning die-to-wafer bonding process. In an example, the alignment difference between the bonding surfaces and the interconnects is within 500 nanometer (nm) or less.

Like the non-elevated portion 115 of the wafer 110, in an example, the non-elevated portion 140 of the semiconductor die 130 includes a hydrophobic layer 150 or material. The hydrophobic layer 150 helps create a or define a liquid confinement area for the semiconductor die 130. In an example, the hydrophobic layer 150 covers or substantially covers the non-elevated portion 140 of the semiconductor die 130. Additionally, the hydrophobic layer 150 extends, at least partially, along a sidewall of the elevated portion 135 of the semiconductor die 130.

The semiconductor die 130 also includes a backside pad 155 and a backside dielectric 160. The backside pad 155 and the backside dielectric 160 enable the semiconductor package 100 to be electrically coupled to other semiconductor packages, other electronic components and/or a printed circuit board (PCB). In an example, the backside pad 155 is associated with one or more vias 165. In an example, the vias 165 provide routing capabilities and/or routing paths between different metal layers of the semiconductor die 130 and/or electrically and/or communicatively couple the backside pad 155 to various interconnects of the semiconductor package 100. In one example, the vias 165 are through silicon vias (TSVs). While the vias 165 electrically and/or communicatively couple the backside pad 155 to the various interconnects of the semiconductor package 100, the backside dielectric 160 provides support and/or a contact/bonding surface for the semiconductor package 100.

In an example, the semiconductor package 100 also includes an encapsulation material 170. The encapsulation material 170 may be comprised of any suitable epoxy molding compound or other material. The encapsulation material 170 surrounds or encapsulates at least a portion of the wafer 110 and the semiconductor die 130. For example, the encapsulation material 170 at least partially encloses or at least partially surrounds the elevated portion 105 of the wafer 110, the non-elevated portion of the wafer 110, the elevated portion 135 of the semiconductor die 130 and/or the non-elevated portion 140 of the semiconductor die 130. The encapsulation material 170 provides support and protection for the various components of the semiconductor package 100.

FIG. 2-FIG. 12 illustrate a surface preparation process of the self-aligning die-to-wafer bonding process that may be used to manufacture or assemble a semiconductor package, such as, for example, the semiconductor package 100 shown and described with respect to FIG. 1. In an example, each operation of the surface preparation process described herein may be used on a wafer (e.g., a CMOS wafer) and/or on one or more semiconductor dies. For example, the various operations shown and described with respect to FIG. 2-FIG. 12 are performed on a wafer and/or on semiconductor dies prior to any dicing and/or other separation operations being performed on the wafer and/or on the semiconductor dies.

As previously discussed, the surface preparation process helps ensure the bonding surfaces (e.g., elevated portions) of the wafer and/or the semiconductor die are smooth and are free from debris and other contaminants. As a result, a bond quality and a signal quality of the interconnects is increased when compared with conventional die-to-wafer bonding techniques.

In the examples that follow, the surface preparation process will be described with respect to the wafer. However, as explained above, the processes described below may be equally applicable to the semiconductor die. Additionally, in the following figures, like numbering represents like elements between the figures.

FIG. 2 illustrates a wafer 200 for a semiconductor package undergoing a first operation of a surface preparation process that is part of a self-aligning die-to-wafer bonding process according to an example. In an example, the wafer 200 is similar to the wafer 110 shown and described with respect to FIG. 1.

As shown in FIG. 2, the wafer 200 includes one or more interconnects 210. The interconnects are provided on a top surface, or a first surface, of the wafer 200. In an example, the interconnects are copper pads, although other connection points and/or connection mechanisms are contemplated.

In the first operation of the surface preparation process, a photoresist layer 220 is provided on the first surface of the wafer 200. In an example, the photoresist layer 220 is provided on the first surface of the wafer 200 using a spin coating process or other suitable process. The photoresist layer 220 covers or substantially covers the first surface of the wafer 200 and the interconnects 210.

FIG. 3 illustrates the wafer 200 of FIG. 2 undergoing a second operation of the surface preparation process according to an example. In an example, the second operation includes a lithography process that will be used to define an elevated portion, or a mesa, of the wafer 200 and a non-elevated portion of the wafer 200. For example, a portion of the photoresist layer 220 is removed from the first surface of the wafer 200 while a remaining portion of the photoresist layer 220 is hardened or otherwise developed. In an example, a size of the elevated portion, or the mesa, is based, at least in part, on the remaining amount of the photoresist layer 220.

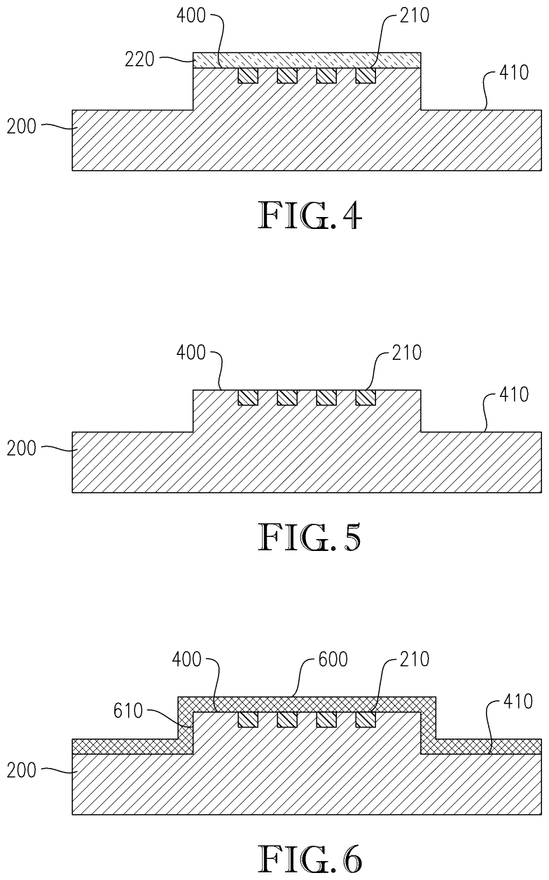

FIG. 4 illustrates the wafer 200 of FIG. 3 undergoing a third operation of the surface preparation process according to an example. During the third operation, an etching process (e.g., a plasma etching process or a dry etching process) is used to form or define the elevated portion 400, or the mesa, of the wafer 200 and to define the non-elevated portion 410 of the wafer 200.

In an example, the non-elevated portion 410 and the elevated portion 400 create a physical contrast on the first surface of the wafer 200 which defines a liquid confinement area on the wafer. For example, the elevated portion 400 helps contain a liquid on a bonding surface (e.g., an exposed surface of the elevated portion 400) of the wafer 200.

In an example, the elevated portion 400 of the wafer has a thickness or a height of between 5 nanometers (nm) and 100 nm. The non-elevated portion 410 of the wafer 200 may have any thickness and/or height. For example, the thickness and/or a height of the non-elevated portion 410 may be consistent with industry standards and/or may be based on a specific need and/or design of a semiconductor package. Although specific values are given, the non-elevated portion 410 and the elevated portion 400 may have any desired thicknesses and/or heights.

FIG. 5 illustrates the wafer 200 of FIG. 4 undergoing a fourth operation of the surface preparation process according to an example. As shown in FIG. 5, the remaining portions of the photoresist layer 220 (FIG. 2) are removed from the elevated portion 400 of the wafer 200. In an example, any suitable solvent may be used to remove the remaining portions of the photoresist layer 220 from the elevated portion 400.

FIG. 6 illustrates the wafer 200 of FIG. 5 undergoing a fifth operation of the surface preparation process according to an example. In an example, the fifth operation includes providing a hydrophobic material, or forming a hydrophobic layer 600, on the wafer 200. The hydrophobic layer 600 is provided on the wafer 200 using any suitable spin coating process or technique and/or is formed using any suitable hydrophobic material. In an example, a thickness of the hydrophobic layer 600 is based, at least in part, on the type of the layer. For example, for fluoropolymer-based hydrophobic layers, the thickness of the hydrophobic layer 600 may be between 50 nm and 500 nm and for self-assembled monolayers (SAMs), the thickness is typically between 1 nm and 3 nm. Although a specific range is given, the hydrophobic layer 600 may have any desired thickness.

As shown in FIG. 6, the hydrophobic layer 600 entirely covers, or substantially covers the non-elevated portion 410 of the wafer 200, the elevated portion 400 of the wafer 200, one or more sidewalls 610 of the elevated portion 400 of the wafer 200 and the interconnects 210 of the wafer 200. In an example, the hydrophobic layer 600 helps define the liquid confinement area on the wafer 200. For example, the hydrophobic layer 600 creates a chemical contrast between the elevated portion 400 of the wafer 200 and the non-elevated portion 410 of the wafer 200 which helps ensure that the liquid is confined to the elevated portion 400 of the wafer during the self-aligning die-to-wafer bonding process.

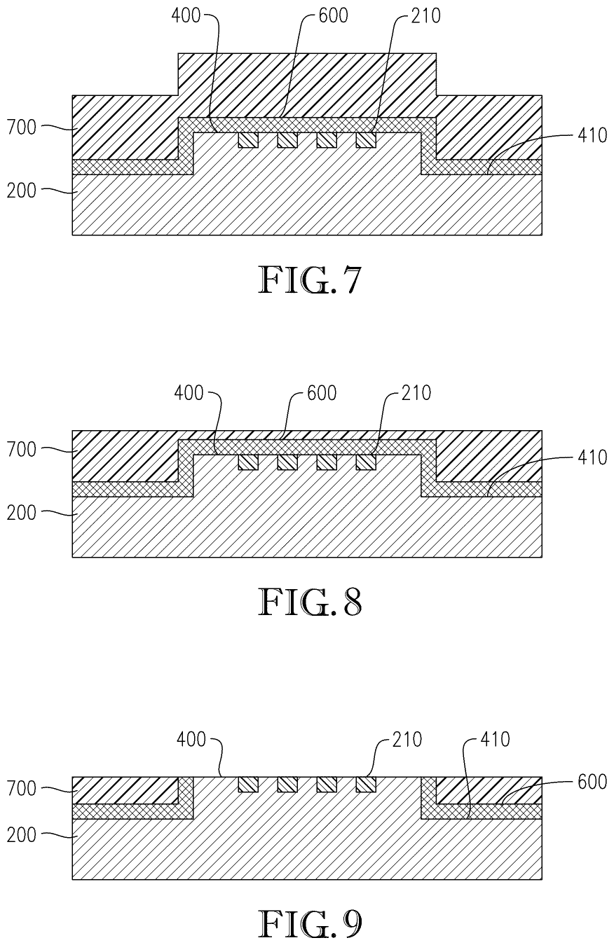

FIG. 7 illustrates the wafer 200 of FIG. 6 undergoing a sixth operation of the surface preparation process according to an example. In the sixth operation, a polymer film 700 is provided over the first surface of the wafer 200. For example, the polymer film 700 is provided on or over the hydrophobic layer 600, the elevated portion 400 and the non-elevated portion 410.

In an example, the polymer film 700 is comprised of Benzocyclobutene (BCB). Although BCB is specifically mentioned, other polymer films may be used.

The polymer film 700 is provided over the first surface of the wafer 200 using any suitable spin coating process or technique. In an example, a thickness of the polymer film 700 is greater than a difference in the thickness and/or height between the elevated portion 400 and the non-elevated portion 410 of the wafer 200. For example, the thickness of the polymer film 700 is in a between 500 nm and 1 micrometer (μm). Although a specific range is given, the polymer film 700 may have any desired thickness.

FIG. 8 illustrates the wafer 200 of FIG. 7 undergoing a seventh operation of the surface preparation process according to an example. In this example, the seventh operation is used to flatten the bonding surface of the elevated portion 400. For example, a chemical/mechanical polishing (CMP) process is used to thin (or remove) the polymer film 700 from the bonding surface (or the top surface) of the elevated portion 400. The bonding surface of the elevated portion 400 may also be cleaned (e.g., using deionized water or another liquid) and subsequently dried.

FIG. 9 illustrates the wafer 200 of FIG. 8 undergoing an eighth operation of the surface preparation process according to an example. In an example, the eighth operation includes performing an etching process on the elevated portion 400 of the wafer 200. In an example, the etching process of the eighth operation may be any suitable etching process including, but not limited to, plasma etching or dry etching (e.g., using a low-pressure, low-power fluorine plasma or a low-power oxygen plasma).

The etching process is used to fully remove any remaining portions of the polymer film 700 and/or the hydrophobic layer 600 from the elevated portion 400. As a result, the bonding surface of the elevated portion 400 of the wafer 200, and the interconnects 210, are fully exposed.

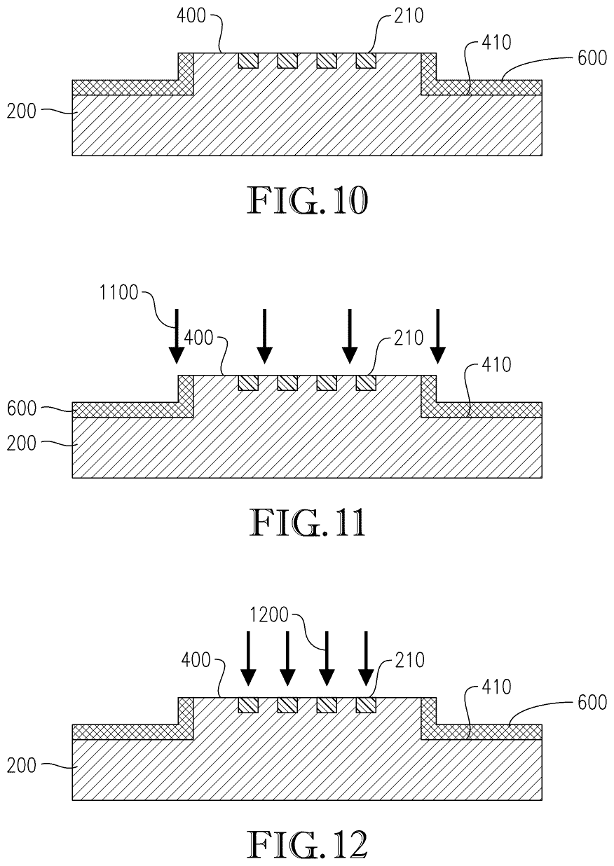

FIG. 10 illustrates the wafer of FIG. 9 undergoing a ninth operation of the surface preparation process according to an example. In an example, the ninth operation includes removing any remaining portions of the polymer film 700. For example, any remaining portions of the polymer film 700 are removed from the non-elevated portion 410 of the wafer 200 using a solvent (e.g., a chemical solvent such as, for example, mesitylene, xylenes, etc.). The non-elevated portion 410 and/or the elevated portion 400 may also be cleaned and/or dried.

In an example, a second CMP process may be used to further flatten and smooth the bonding surface and/or the interconnects 210 of the elevated portion 400. For example, the etching process described in the eighth operation may have caused the bonding surface of the elevated portion 400 to become rough. As a result, the CMP process of the ninth operation can be used to smooth and/or flatten any rough patches or elevation inconsistencies that may be present on the bonding surface and/or on the interconnects 210.

In an example and following the second CMP process, the wafer 200 is rinsed and dried. In an example, the wafer 200 is dried using a nitrogen gas, or a nitrogen gas drying process. Although nitrogen gas is specifically mentioned, other drying techniques and processes may be used.

FIG. 11 illustrates the wafer of FIG. 10 undergoing a tenth operation of the surface preparation process according to an example. In an example, the tenth operation includes causing the bonding surface of the elevated portion 400 to have hydrophilic properties and/or applying hydrophilic inducing materials to the elevated portion 400 of the wafer. In an example, this is achieved by applying a plasma treatment (represented by the arrows 1100) to at least the elevated portion 400 of the wafer 200. In an example, the plasma treatment is a low power or a pulsed oxygen-based plasma treatment. In another example, the plasma treatment is a ultraviolet (UV)-Ozone treatment. Although specific examples are given, other materials and/or processes may be used to cause the elevated portion 400 to have hydrophilic properties.

In an example and following the tenth operation, the wafer 200 is rinsed and dried. In an example, the wafer 200 is rinsed using deionized water (or another liquid) and is dried using a nitrogen gas, or a nitrogen gas drying process. Although nitrogen gas is specifically mentioned, other drying techniques and/or processes can be used.

FIG. 12 illustrates the wafer 200 of FIG. 11 undergoing an eleventh operation of the surface preparation process according to an example. In an example, the eleventh operation including de-oxidizing the interconnects 210. For example, the interconnects 210 may be made from copper and the various operations previously described may have caused the interconnects 210 to oxidize. As a result, a hydrogen plasma treatment (represented by the arrows 1200) may be used to de-oxidize the interconnects 210. Although a hydrogen plasma treatment is described, other de-oxidization processes may be used. Upon completion of the eleventh operation, the wafer 200 is rinsed (e.g., using deionized water) and dried (e.g., using nitrogen gas).

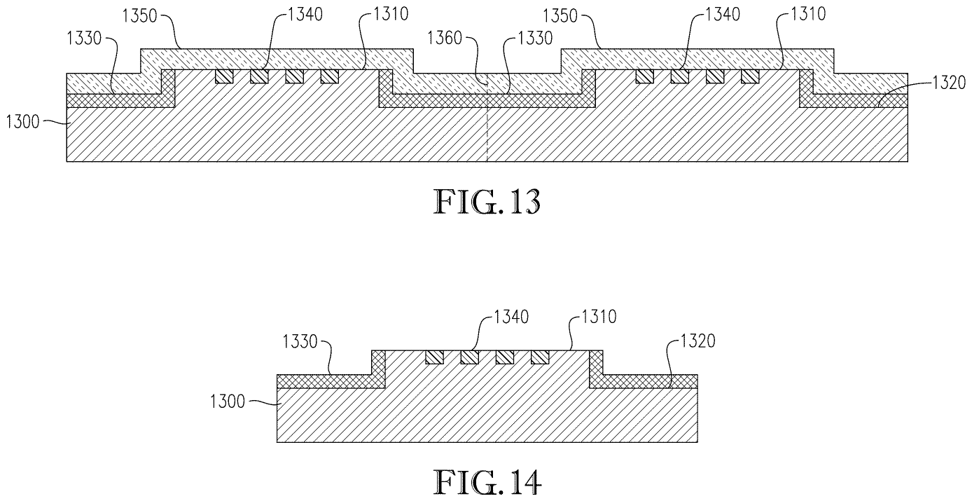

FIG. 13-FIG. 14 illustrate additional operations that are part of the surface preparation process of the self-aligning die-to-wafer bonding process. However, in some examples, the operations shown and described with respect to FIG. 13-FIG. 14 are only applicable to a semiconductor die (e.g., the semiconductor die 130 (FIG. 1)). In some examples, the semiconductor dies have not been diced or otherwise separated. As such, additional operations may be required to help ensure the bonding surface of the semiconductor die is free from debris and/or contaminants. Additionally, the operations shown and described with respect to FIG. 13-FIG. 14 occur after the eleventh operation described with respect to FIG. 12.

FIG. 13 illustrates semiconductor dies 1300 undergoing a twelfth operation of the surface preparation process according to an example. As previously discussed, the semiconductor dies 1300 may be similar to the semiconductor die 130 shown and described with respect to FIG. 1. However, in this example, the semiconductor dies 1300 have yet to undergo a dicing process.

In this example, each of the semiconductor dies 1300 include an elevated portion 1310 and a non-elevated portion 1320. A hydrophobic layer 1330 is provided on the non-elevated portion 1320 to define a liquid confinement area. As previously described, the elevated portion 1310 includes one or more interconnects 1340.

In an example, the twelfth operation includes applying a photoresist layer 1350 to the semiconductor dies 1300. In an example, the photoresist layer 1350 is applied to the semiconductor dies 1300 using any suitable coating technique (e.g., a spin coating technique). The photoresist layer 1350 helps protect the bonding surface of the semiconductor die 1300 and/or the interconnects 1340 of the semiconductor die from damage and/or debris that may occur as a result of a dicing process. Once the photoresist layer 1350 has been applied to the semiconductor die 1300, the semiconductor dies are diced (e.g., indicated by the dotted line 1360). In an example, laser or plasma dicing may be used.

FIG. 14 illustrates the semiconductor die 1300 of FIG. 13 undergoing a thirteenth operation of the surface preparation process according to an example. In this example, the thirteenth operation includes removing the photoresist layer 1350 from the elevated portion 1310 and the non-elevated portion 1320. In an example, any suitable solvent may be used to remove the photoresist layer 1350 from the semiconductor die 1300. The semiconductor die is then rinsed (e.g., using deionized water) and dried (e.g., using nitrogen gas).

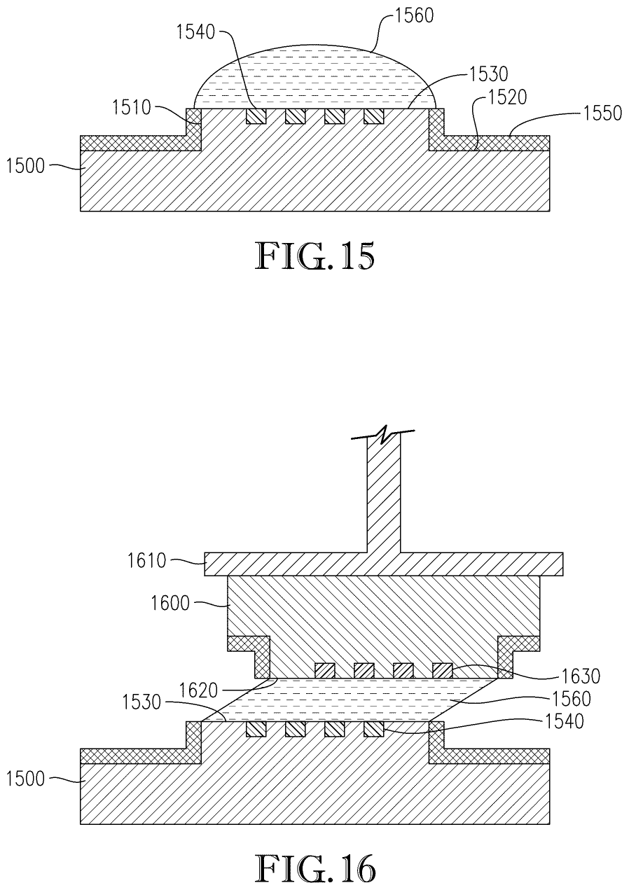

FIG. 15 illustrates a first operation of a self-aligning die-to-wafer bonding process according to an example. In an example, the first operation of the self-aligning die-to-wafer bonding process is performed after the thirteenth operation shown and described with respect to FIG. 14 (e.g., with respect to a semiconductor die) has been completed and/or after the eleventh operation shown and described with respect to FIG. 12 (e.g., with respect to a wafer) has been completed.

In an example, the first operation of the self-aligning die-to-wafer bonding process occurs on a wafer 1500. In an example, the wafer 1500 is similar to wafer 200 shown and described with respect to FIG. 2-FIG. 12. For example, the wafer 1500 includes an elevated portion 1510 and a non-elevated portion 1520. A bonding surface 1530 comprising a plurality of interconnects 1540 are provided on the elevated portion 1510. In an example, the non-elevated portion, 1520 along with one or more sidewalls of the elevated portion 1510 include a hydrophobic layer 1550.

The first operation of the self-aligning die-to-wafer bonding process includes placing or providing a liquid 1560 on the bonding surface 1530 of the wafer 1500. In an example, the liquid 1560 is deionized water. Although deionized water is specifically mentioned, other liquids may be used.

In an example, the hydrophobic layer 1550, along with the elevated portion 1510 and hydrophilic properties of the bonding surface 1530, define a liquid confinement area. As such, the liquid 1560 will remain on the bonding surface 1530 of the elevated portion 1510 of the wafer 1500. Although FIG. 15 shows liquid being applied to a single elevated portion 1510 of a single wafer 1500, it is contemplated that the wafer 1500 may be part of a single, larger, and/or unsingulated semiconductor wafer. As such, the liquid 1560 may be applied to multiple elevated portions of the wafer 1500.

FIG. 16 illustrates a second operation of the self-aligning die-to-wafer bonding process shown and described with respect to FIG. 15 according to an example. In the second operation, a pick and place machine 1610 causes a bonding surface 1620 (e.g., an exposed surface of an elevated portion) of a semiconductor die 1600 to contact the liquid 1560. In an example, the semiconductor die 1600 is similar to the semiconductor die 130 shown and described with respect to FIG. 1 and/or the semiconductor die 1300 shown and described with respect to FIG. 13-FIG. 14.

In an example, the pick and place machine 1610 “loosely” aligns the bonding surface 1530 of the wafer 1500 and bonding surface 1620 of the semiconductor die 1600 and/or “loosely” aligns the interconnects 1540 of the wafer 1500 with the interconnects 1630 of the semiconductor die 1600. In an example, the alignment is in a range of 50 micrometers (μm) and 150 μm. Although a specific range is given, the alignment may be greater than 150 μm or less than 50 μm.

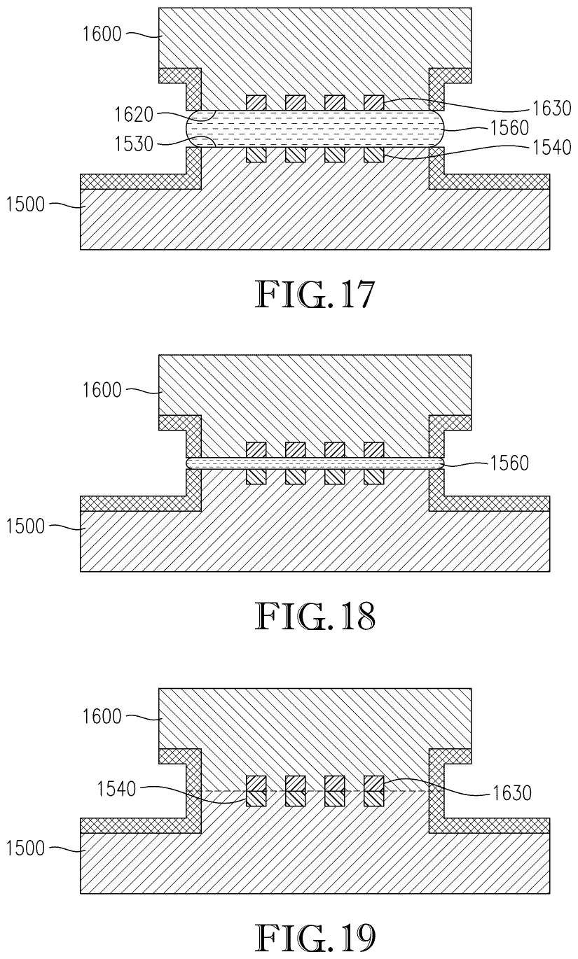

FIG. 17 illustrates a third operation of the self-aligning die-to-wafer bonding process shown and described with respect to FIG. 16 according to an example. In an example, once the bonding surface 1620 of the semiconductor die 1600 has been loosely aligned with the bonding surface 1530 of the wafer 1500, the pick and place machine 1610 releases the semiconductor die 1600. Once released, a capillary force of the liquid 1560, along with the liquid confinement area defined by the various hydrophobic layers, causes the semiconductor die 1600 to be aligned with the wafer 1500. For example, the capillary force of the liquid 1560 causes the interconnects 1540 of the wafer 1500 to be aligned within 500nm of the interconnects 1630 of the semiconductor die 1600.

FIG. 18 illustrates a fourth operation of the self-aligning die-to-wafer bonding process shown and described with respect to FIG. 17 according to an example. In this operation, the liquid 1560 is evaporated. In an example, the liquid 1560 may evaporate under natural conditions. In another example, the speed of the evaporation may be increased by subjecting the liquid 1560 to increased heat or increased environmental temperatures.

FIG. 19 illustrates a fifth operation of the self-aligning die-to-wafer bonding process shown and described with respect to FIG. 18 according to an example. In this example, the liquid between the wafer 1500 and the semiconductor die 1600 has been fully evaporated. As such, the bonding surface and the interconnects 1630 of the semiconductor die 1600 directly contact the bonding surface and the interconnects 1540 of the wafer 1500. An annealing process (e.g., bond annealing) is used to couple the semiconductor die 1600 to the wafer 1500.

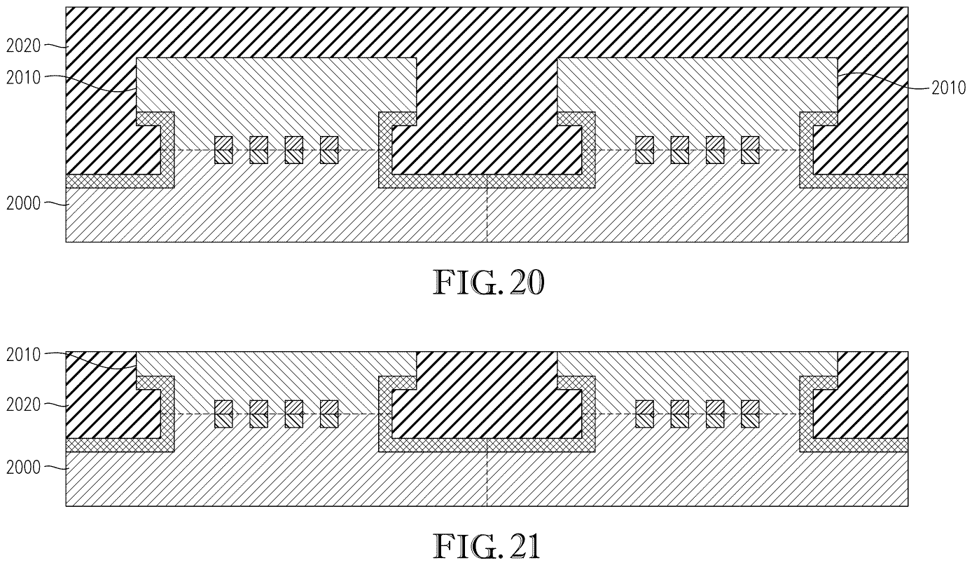

FIG. 20-FIG. 24 illustrate a semiconductor package assembly process. In an example, the semiconductor package assembly process may be used to create the semiconductor package 100 shown and described with respect to FIG. 1. Additionally, the semiconductor package assembly process may occur after the fifth operation of the self-aligning die-to-wafer bonding process shown and described with respect to FIG. 19.

FIG. 20 illustrates a first operation of a semiconductor package assembly process according to an example. In an example, the first operation of the semiconductor package assembly process occurs when a wafer 2000 and a semiconductor die 2010 have been bonded together such as previously described. In an example, the wafer 2000 is similar to the various wafers shown and described herein. Likewise, the semiconductor die 2010 is similar to the various semiconductor dies shown and described herein.

When bonding surfaces of a plurality of semiconductor dies 2010 have been placed on, and bonded with, respective bonding surfaces of a wafer 2000, one or more edges of the wafer 2000 are trimmed. An encapsulating material 2020 (or an epoxy material) is used to at least partially surround and/or encapsulate the semiconductor dies 2010 and the wafer 2000. For example, the encapsulating material 2020 may at least partially encapsulate an elevated portion of the wafer 2000 and/or an elevated portion of each of the semiconductor dies 2010.

In an example, the encapsulating material is an epoxy resin. Although an epoxy resin is specifically mentioned, any encapsulating material may be used. Regardless of the material, the encapsulating material protects the various electronic components and traces associated with the wafer 2000 and/or the semiconductor dies 2010, provides strength and support and may provide a number of other functions (e.g., heat dissipation).

FIG. 21 illustrates a second operation of the semiconductor package assembly process according to an example. In the second operation, the encapsulating material 2020 (e.g., on the semiconductor die 2010 side) and/or the backside of the semiconductor die 2010 is/are thinned. The second operation prepares the semiconductor die 2010 for an upcoming metallization process. In an example, the encapsulating material 2020 and/or the semiconductor die 2010 is/are thinned or reduced using a grinding process and/or a CMP process. In an example, once the encapsulating material 2020 and/or the semiconductor die 2010 have been thinned, a backside surface of the semiconductor die 2010 is washed (e.g., using deionized water) and dried.

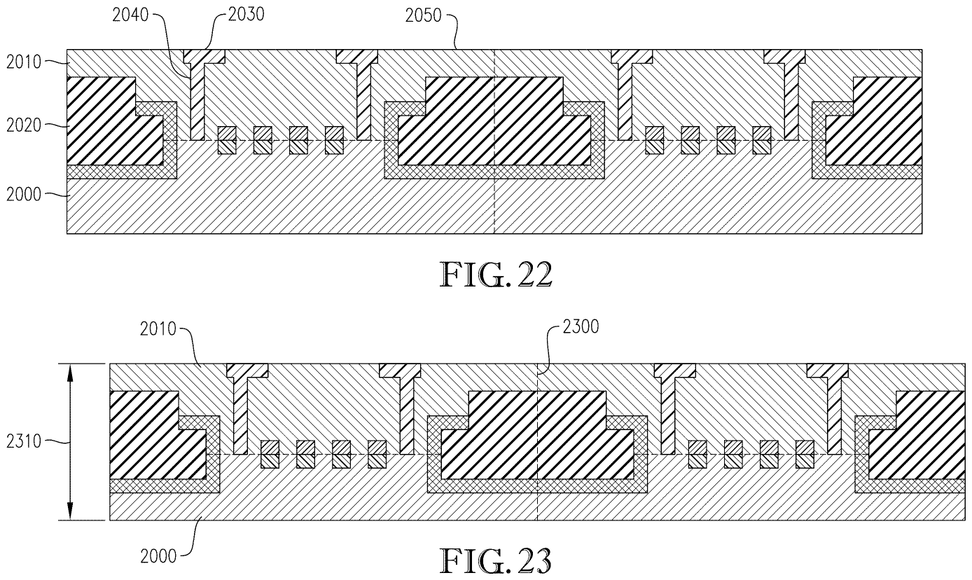

FIG. 22 illustrates a third operation of the semiconductor package assembly process according to an example. In an example, the third operation includes adding a backside dielectric layer 2050 to the semiconductor dies 2010 and/or performing a metallization process on the semiconductor dies 2010. The metallization process may include adding one or more backside pads 2030 to the semiconductor die 2010 and/or adding one or more vias 2040 to the semiconductor die 2010. In an example, the backside pads 2030 and the vias 2040 connect to the interconnects of the semiconductor die 2010 and/or the interconnects of the wafer 2000.

In an example, the vias 2040 are through silicon vias (TSVs). In another example, the vias 2040 are routing vias that connect adjacent metal layers to the various interconnects and ultimately between any signal/power interconnect (contained in the post-bonding structure) to the backside pads 2030.

FIG. 23 illustrates a fourth operation of the semiconductor package assembly process according to an example. In this operation, the wafer 2000 (e.g., a backside of the wafer 2000) is thinned using a grinding process and/or a CMP process. In an example, the thinning operation causes a thickness or a height 2310 of an individual semiconductor package to be in a range of 50 μm and 100 μm. Although a specific range is given, the thickness and/or height of the semiconductor package may have any desired thickness and/or height. Upon completion of the fourth operation, the wafer 2000 and the semiconductor die 2010 are diced (e.g., along the dotted line 2300).

Based on the above, examples of the present disclosure describe a method, comprising: forming a mesa on a surface of a wafer, the mesa including at least one bond pad; providing a hydrophobic material on the surface of the wafer such that at least a portion of the mesa is covered by the hydrophobic material; covering at least a portion of the hydrophobic material with a polymer film; removing the hydrophobic material and the polymer film from a surface of the mesa; removing a remaining portion of the polymer film from the surface of the wafer; and de-oxidizing the at least one bond pad. In an example, the method also includes dispensing a liquid on the surface of the mesa. In an example, the method also includes placing a surface of a mesa of an array die at least partially on the liquid; causing the liquid to evaporate; and bonding the at least one bond pad on the wafer to a corresponding bond pad of the array die. In an example, the method also includes encapsulating at least a portion of the wafer and at least a portion of the array die with an epoxy material. In an example, the method also includes thinning at least a portion of the epoxy material and at least a portion of the array die. In an example, the method also includes performing a metallization process on the array die. In an example, the method also includes thinning at least a portion of the wafer. In an example, the method also includes providing a photoresist layer on the surface of the wafer prior to forming the mesa. In an example, the method also includes removing at least portion of the photoresist layer on the surface of the wafer to define the mesa, the mesa being defined by a remaining portion of the photoresist layer. In an example, the method also includes removing the remaining portion of the photoresist layer on the mesa in response to the mesa being formed. In an example, a thickness of the polymer film is greater than a height of the mesa. In an example, the hydrophobic material and the polymer film is removed from the surface of the mesa by an etching process. In an example, the method also includes performing a chemical mechanical polishing process on the surface of the mesa upon completion of the etching process. In an example, the method also includes treating the surface of the mesa with a hydrophilic material.

Examples also describe a semiconductor package, comprising: a wafer having an elevated portion and a non-elevated portion, the elevated portion of the wafer having at least one bond pad and hydrophilic properties; a hydrophobic layer covering at least a portion of the non-elevated portion of the wafer and at least a portion of a sidewall of the elevated portion of the wafer; an array dielet having an elevated portion and non-elevated portion, the elevated portion of the array dielet having at least one bond pad and hydrophilic properties, the at least one bond pad of the array dielet being bonded to the at least one bond pad of the wafer; a hydrophobic layer covering at least a portion of the non-elevated portion of the array dielet and at least a portion of a sidewall of the elevated portion of the array dielet; and an epoxy molding compound at least partially encapsulating the elevated portion of the array dielet and the elevated portion of the wafer. In an example, the semiconductor package has a thickness of between fifty micrometers (μm) and one hundred μm. In an example, the elevated portion of the array dielet was aligned with the elevated portion of the wafer using capillary force.

Examples also describe a semiconductor package, comprising: a wafer having a first liquid confinement area, the first liquid confinement area including a first interconnection means and having hydrophilic properties; a first liquid repelling means defining the first liquid confinement area; a semiconductor die having a second liquid confinement area, the second liquid confinement area including a second interconnection means and having a hydrophilic properties; a second liquid repelling means defining the second liquid confinement area; and an encapsulation means at least partially encapsulating the wafer and the semiconductor die. In an example, the first interconnection means is directly coupled to the second interconnection means. In an example, the first liquid confinement area was aligned with the second liquid confinement area using capillary force.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an example with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to schematic flowchart diagrams and/or schematic block diagrams of methods, apparatuses, systems, and computer program products according to examples of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute by way of the processor or other programmable data processing apparatus, create means for implementing the functions and/or acts specified in the schematic flowchart diagrams and/or schematic block diagrams block or blocks.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A method, comprising:
forming a mesa on a surface of a wafer, the mesa including at least one bond pad;
providing a hydrophobic material on the surface of the wafer such that at least a portion of the mesa is covered by the hydrophobic material;
covering at least a portion of the hydrophobic material with a polymer film;
removing the hydrophobic material and the polymer film from a surface of the mesa;
removing a remaining portion of the polymer film from the surface of the wafer; and
de-oxidizing the at least one bond pad.

2. The method of claim 1, further comprising dispensing a liquid on the surface of the mesa.

3. The method of claim 2, further comprising:
placing a surface of a mesa of an array die at least partially on the liquid;
causing the liquid to evaporate; and
bonding the at least one bond pad on the wafer to a corresponding bond pad of the array die.

4. The method of claim 3, further comprising encapsulating at least a portion of the wafer and at least a portion of the array die with an epoxy material.

5. The method of claim 4, further comprising thinning at least a portion of the epoxy material and at least a portion of the array die.

6. The method of claim 5, further comprising performing a metallization process on the array die.

7. The method of claim 6, further comprising thinning at least a portion of the wafer.

8. The method of claim 1, further comprising providing a photoresist layer on the surface of the wafer prior to forming the mesa.

9. The method of claim 8, further comprising removing at least portion of the photoresist layer on the surface of the wafer to define the mesa, the mesa being defined by a remaining portion of the photoresist layer.

10. The method of claim 9, further comprising removing the remaining portion of the photoresist layer on the mesa in response to the mesa being formed.

11. The method of claim 1, wherein a thickness of the polymer film is greater than a height of the mesa.

12. The method of claim 1, wherein the hydrophobic material and the polymer film is removed from the surface of the mesa by an etching process.

13. The method of claim 12, further comprising performing a chemical mechanical polishing process on the surface of the mesa upon completion of the etching process.

14. The method of claim 1, further comprising treating the surface of the mesa with a hydrophilic material.

15. A semiconductor package, comprising:
a wafer having an elevated portion and a non-elevated portion, the elevated portion of the wafer having at least one bond pad and hydrophilic properties;
a hydrophobic layer covering at least a portion of the non-elevated portion of the wafer and at least a portion of a sidewall of the elevated portion of the wafer;
an array dielet having an elevated portion and non-elevated portion, the elevated portion of the array dielet having at least one bond pad and hydrophilic properties, the at least one bond pad of the array dielet being bonded to the at least one bond pad of the wafer;
a hydrophobic layer covering at least a portion of the non-elevated portion of the array dielet and at least a portion of a sidewall of the elevated portion of the array dielet; and
an epoxy molding compound at least partially encapsulating the elevated portion of the array dielet and the elevated portion of the wafer.

16. The semiconductor package of claim 15, wherein the semiconductor package has a thickness of between fifty micrometers (μm) and one hundred μm.

17. The semiconductor package of claim 15, wherein the elevated portion of the array dielet was aligned with the elevated portion of the wafer using capillary force.

18. A semiconductor package, comprising:
a wafer having a first liquid confinement area, the first liquid confinement area including a first interconnection means and having hydrophilic properties;
a first liquid repelling means defining the first liquid confinement area;
a semiconductor die having a second liquid confinement area, the second liquid confinement area including a second interconnection means and having hydrophilic properties;
a second liquid repelling means defining the second liquid confinement area; and
an encapsulation means at least partially encapsulating the wafer and the semiconductor die.

19. The semiconductor package of claim 18, wherein the first interconnection means is directly coupled to the second interconnection means.

20. The semiconductor package of claim 18, wherein the first liquid confinement area was aligned with the second liquid confinement area using capillary force.
